(19) United States
(12) Patent Application Publication
(10) Pub. No.: US 2015/0255659 A1
(43) Pub. Date: Sep. 10, 2015

(54) SOLAR MODULE

(71) Applicant: TSMC Solar Ltd., Taichung City (TW)

(72) Inventor: Chien-Yao HUANG, New Taipei City (TW)

(73) Assignee: TSMC Solar Ltd., Taichung City (TW)

(21) Appl. No.: 14/201,984

(22) Filed: Mar. 10, 2014

(51) Int. Cl. H01L 31/0725; H01L 31/0224; H01L 31/18; H01L 31/0465; H01L 31/0749

(52) U.S. Cl. CPC H01L 31/0725; H01L 31/0465; H01L 31/0749; H01L 31/18; H01L 31/022466

(57) ABSTRACT

A tandem solar module includes first and second thin film solar cell circuits and a transparent coupling layer disposed between the first and second thin film circuits for securing the first and second thin film circuits together in a stack. Each solar cell circuit includes a multi-layer structure, the multi-layer structure including a substrate, a first conductive layer formed over the substrate, a buffer layer, an absorber layer formed between the first conductive layer and the buffer layer, and a second conductive layer formed over the buffer layer. The first thin film solar cell circuit and second thin film solar cell circuit are oriented with respect to one another such that the absorber layers are disposed between the substrates of the circuits. The first and second solar cell circuits have different bandgap profiles.

### BACKGROUND

The present disclosure relates to solar modules and specifically to thin film solar modules.

Conventional thin film solar modules, such as CIS-based solar modules (e.g., copper indium gallium (di)selenide or copper indium aluminum (di)selenide), have only a single junction and their conversion efficiency is limited by large thermalization losses.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a tandem solar module, in accordance with some embodiments.

FIG. 1A illustrates various optical paths through the tandem solar module of FIG. 1, in accordance with some embodiments.

FIG. 2 illustrate the layer structure and bandgap profile of the top circuit of the tandem solar module of FIG. 1 in more detail, in accordance with some embodiments.

FIG. 3 illustrate the layer structure and bandgap profile of the bottom circuit of the tandem solar module of FIG. 1 in more detail, in accordance with some embodiments.

FIG. 4 illustrates a method of fabricating the solar cell circuits and the tandem solar cell module of FIG. 1, in accordance with some embodiments.

FIG. 5 graphically illustrates various energy losses associated with solar cell.

FIG. 6 illustrates certain benefits associated with the tandem solar cell module of FIG. 1, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Likewise, terms concerning electrical coupling and the like, such as “coupled,” “connected” and “interconnected,” refer to a relationship wherein structures communicate with one another either directly or indirectly through intervening structures unless expressly described otherwise.

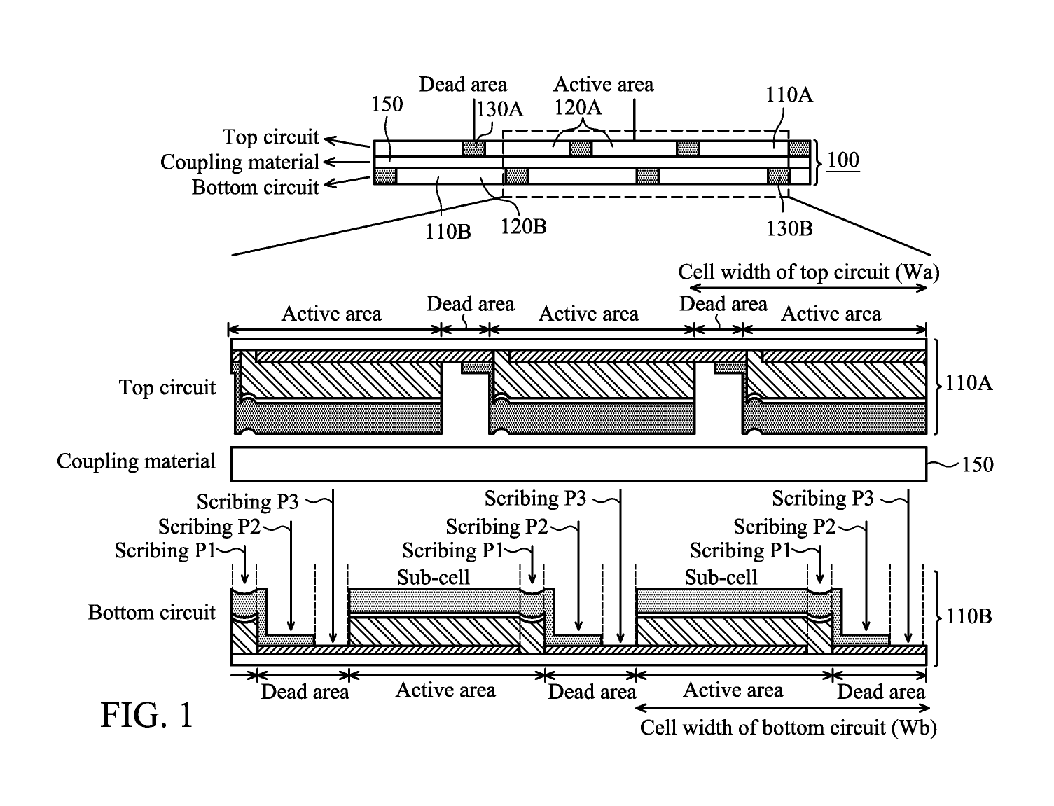

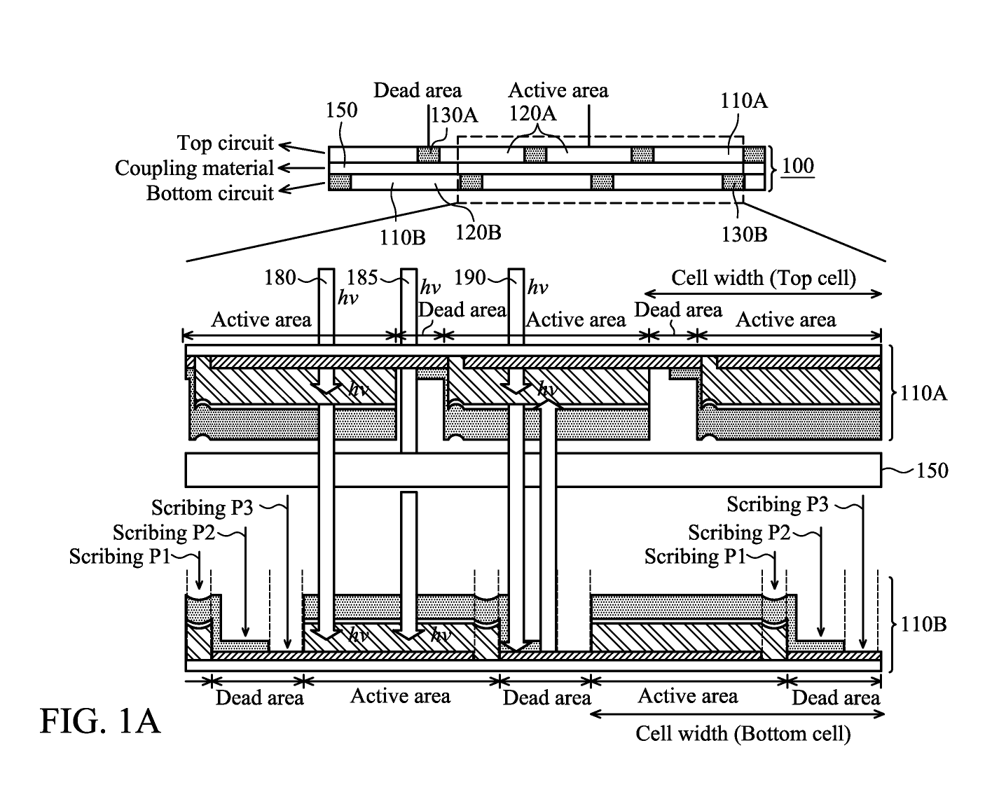

FIG. 1 illustrates an embodiment of a tandem thin film solar module 100. In embodiments, the thin film solar module 100 is a thin film “CIS-based” solar module. The tandem solar module 100 has top thin film solar module circuit or layer 110A and a bottom thin film solar module circuit or layer 110B. The top and bottom circuits 110A, 110B are assembled together by a coupling material layer 150. FIG. 1 also includes an exploded view showing circuits 110A, 110B in more detail. Individual layers of these circuits are described in connection with later figures.

The coupling layer is an translucent material and adheres the top circuit 110A to the bottom circuit 120B. In embodiments, the coupling material layer is an ethylene vinyl acetate (EVA) or poly vinyl acetate (PVA).

Each circuit 110A, 110B is composed of sub-cells by monolithic integration via P1/P2/P3 scribing connections. In embodiments, the top circuit 110A and bottom circuit 110B are separately fabricated with different cell widths Wa (for the top circuit 110A) and Wb (for the bottom circuit 110B). Each circuit has active (sub-cell) areas 120 arranged and separated from one another by dead areas 130. The cell width is the combined width of an active area 120 and a dead area 130.

The layer structure in top circuit 110A and bottom circuit 110B are “mirror” symmetrical with respect to one another, as described in more detail below and as illustrated in the figures. Briefly, the top circuit 110A and bottom circuit 110B are oriented with respect to one another such that the absorber layers are disposed between the substrates of the circuits. Also, in addition to being flipped relative to one another, the top circuit 110A should be arranged in parallel to the bottom circuit 110B such that the scribing lines of the circuits are arranged in parallel rather than perpendicular to one another. The difference in the cell widths also ensures that dead areas 130 in the top and bottom circuits do not align and overlap with one another.

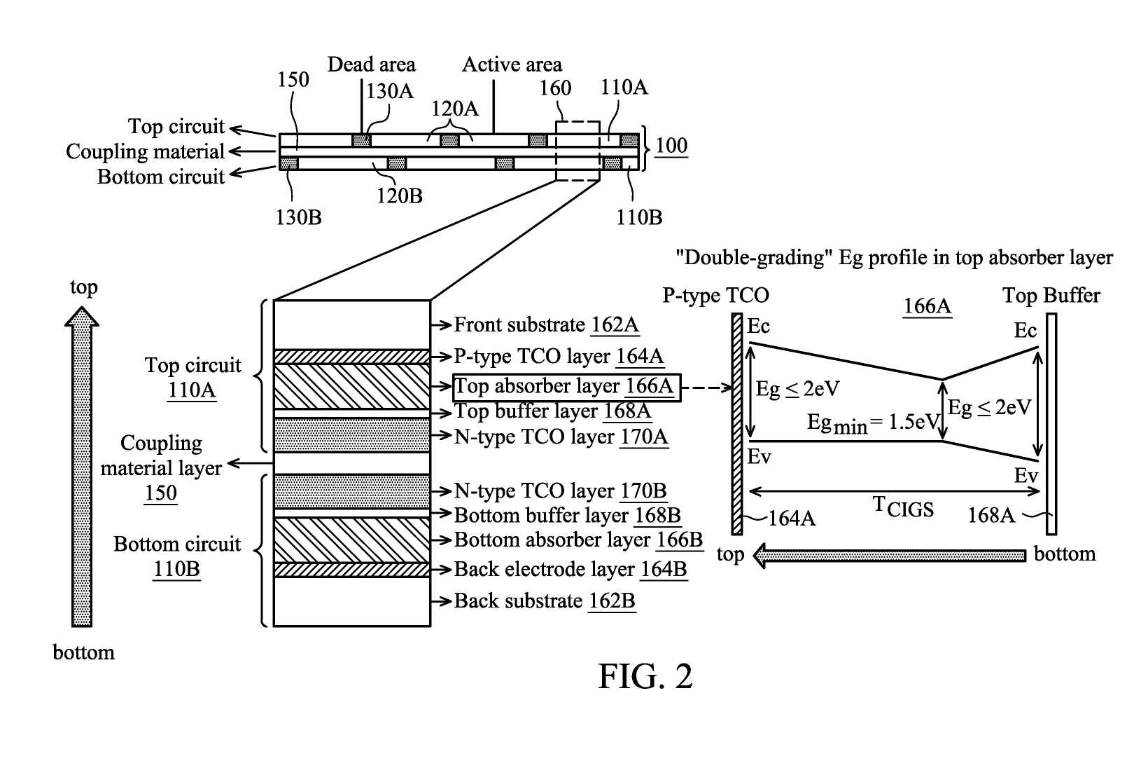

Turning to FIG. 2, FIG. 2 again illustrates the embodiment of a tandem thin film solar module 100 with particular emphasis on the layer structure of overlapping sub-cell region 160. Turning first to the sub-cell region of the thin film top circuit 110A is composed of five material layers 162A to 170A:

(1) A front substrate layer 162A, such as formed from glass or plastic.

(2) A p-type TCO (transparent conducting oxide (i.e., optically transparent and electrically conductive)) layer 164A, such as, in embodiments, a TCO layer selected from a group of In₂O₃:Sn (ITO), SnO₂:F (FTO), ZnO:Al (AZO), and ZnO:B (BZO). In embodiments, this p-type TCO layer 164A has an optical transmittance ≧90%, a sheet resistance ≦15 ohmn/square centimeters, and a temperature tolerance ≧600° C.

(3) A “top” absorber layer 166A that is, in embodiments, selected from a group of Cu(In,Al)(Se,S)₂ and Cu(In,Ga)(Se,S)₂ compounds. The thickness of the top absorber layer 166A is ≧100 nm.

(4) A “top” buffer layer 168A, such as one formed of cadmium sulfide (CdS). In embodiments, the thickness of “top buffer layer” is ≧30 nm.

As illustrated on the right side of FIG. 2, in embodiments, this “top absorber layer” has a double-graded band gap (Eg) profile which has an minimum band gap 1.5 eV inside and increasing band gaps towards the top and bottom surfaces adjacent the p-type TCO layer 164A and top buffer layer 168A, with a maximum band gap ≦2 eV.

The graded band gap toward the top buffer layer 168A is controlled by the gradient of S/(Se+S) ratio in Cu-III-(Se,S)₂ compounds. The graded band gap toward the p-type TCO layer 164A is controlled by the gradient of III atoms in the Cu-III-(Se,S)₂ compounds.

(5) A n-type TCO layer 170A, which in embodiments is a n-type transparent conductive layer selected from a group of ZnO:Al(AZO), ZnO:B(BZO), In₂O3:Sn(ITO), and SnO₂:F(FTO). In embodiments, this n-type TCO layer 170A has an optical transmittance ≧90% and a sheet resistance ≦15 ohmn/square centimeters.

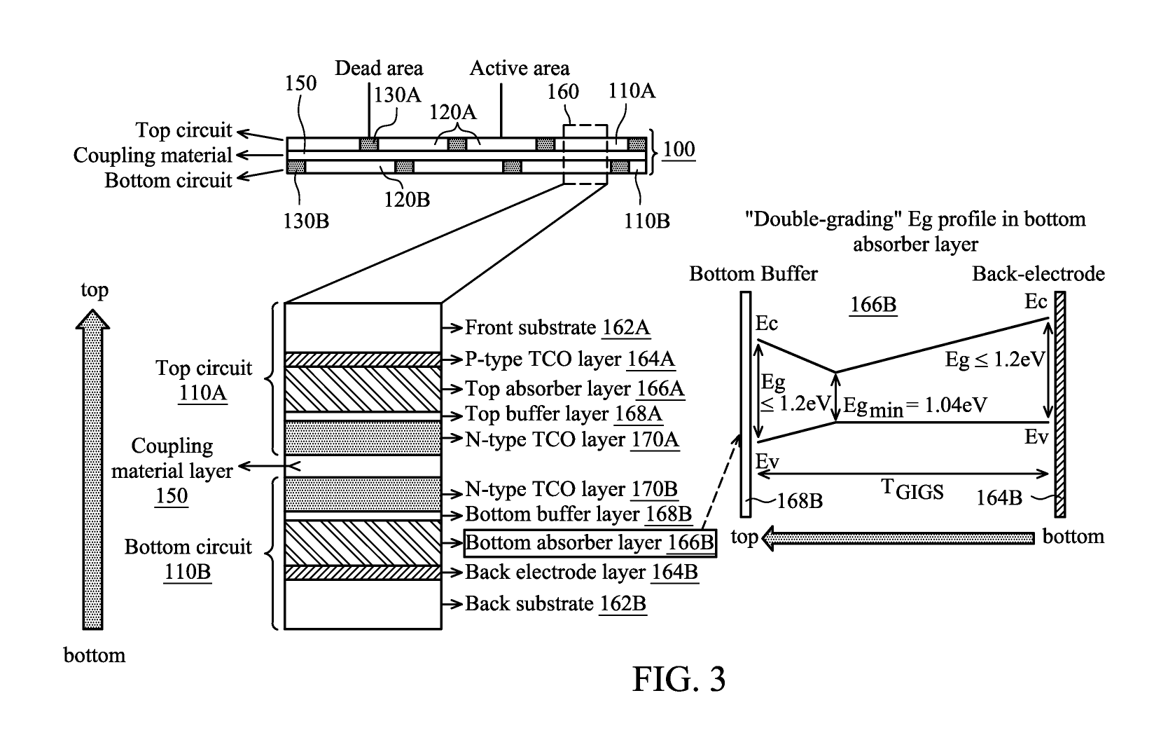

Turning to FIG. 3, FIG. 3 again illustrates the embodiment of a tandem thin film solar module 100 with particular emphasis now on the layer structure of overlapping sub-cell region 160, specifically the sub-cell region of the thin film bottom circuit 110B, which is also composed of five material layers (from bottom to top) 162B to 170B:

(1) A back substrate layer 162B, which may be formed from, for example, glass, metal, foil, or plastic.

(2) A “back” electrode layer 164B, which may be formed from molybdenum.

(3) A “bottom” absorber layer 166B, which in embodiments is composed of Cu(In,Ga)(Se,S)₂ compounds.

(4) A “bottom” buffer layer 168B, which in embodiments is a cadmium sulfide(CdS) layer. The thickness of “bottom buffer layer” may be ≧30 nm.

As shown on the right side of FIG. 3, in embodiments the bottom absorber layer 166B has a double-graded band gap profile which has a minimum band gap of 1.04 eV inside and increasing band gaps toward the top and bottom surface adjacent the bottom buffer layer 168B and back electrode layer 164B, with a maximum band gap ≦1.2 eV. The graded band gap toward the bottom buffer layer 168B is controlled by the gradient of S/(Se+S) ratio in the Cu-III-(Se,S)₂ compounds. The graded band gap toward the back electrode layer 164B is controlled by the gradient of III atoms in Cu-III-(Se,S)₂ compounds.

(5) A n-type TCO layer 170B, which in embodiments is a n-type transparent conductive layer selected from a group of ZnO:Al(AZO), ZnO:B(BZO), In₂O₃:Sn(ITO), and SnO₂:F(FTO). In embodiments, this n-type TCO layer 170B has an optical transmittance ≧90% and a sheet resistance ≦15 ohmn/square centimeters.

It can be seen from FIGS. 2 and 3 that the top circuit 110A and bottom circuit 120B are “mirror” symmetrical with respect to one another. Flipping the top circuit 110A relative to the normal orientation (i.e., with the TCO layer and the top and substrate back electrode and substrate at the bottom) of the bottom circuit 110B provides for better carrier aggregation. If the top circuit were not flipped, i.e., such that its buffer layer 168A were above the absorber layer 166A), then some energy will be lost from absorption by the buffer layer.

As noted above, the top and bottom thin film solar module circuits 110A, 110B are separately fabricated and these two circuits are assembled by a coupling material layer. The electrical interconnect between the top and bottom circuits 110A, 11B could be alternatively series or parallel. This allows for the tailoring the design to either high voltage or high current applications. If a series connection is desired, P-side of the bottom circuit 110B is connected to the N-side of top circuit 110A, and the N-side of the bottom circuit 110B is connected to the P-side of the top circuit 110A. If a parallel connection is desired, the P-side of the bottom circuit 110B is connected to the P-side of the top circuit 110A, and the N-side of the bottom circuit 110B is connected to the N-side of the top circuit 110A. As will be understood by those of ordinary skill, the solar module circuit will have interconnects forming electrical busses that can be connected via external connections (e.g., by leads) to provide the desired series or parallel connections (described above) between the top and bottom circuits 110A and 110B.

The output current difference between the top and bottom circuits causes power loss when the circuits are in series, and the output voltage differences between the top and bottom circuits cause power losses when the circuits are in parallel. In embodiments, this current/voltage mismatch between the top and bottom circuits 110A, 110B will cause power loss when the circuits are series/parallel. Any such mismatch can be reduced by appropriate design of the cell width in the top and bottom circuits. In embodiments, the output current/voltage could be modified by different cell width between the top and bottom circuits, i.e. wider cell width results in higher output current and lower output voltage. Therefore, the mismatch problem could be addressed by modifying cell width in each circuit.

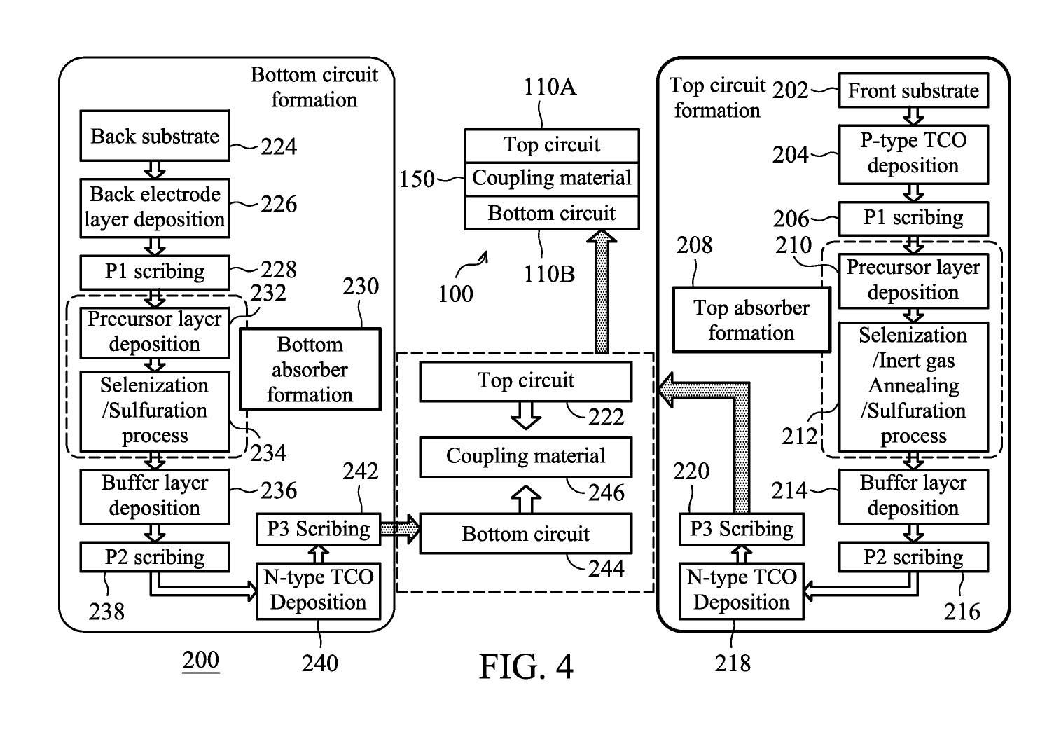

FIG. 4 illustrates an embodiment of a method of forming the tandem thin film solar module 100 described above. The right side of FIG. 4 illustrates steps for forming the top circuit 110A. Specifically, at step 202, the front substrate layer (layer 162A) is provided. At step 204, the P-type TCO layer (layer 164A) is provided on the front substrate layer, such as by a deposition process. At step 206, a P1 scribing operation is performed to provide the P1 scribing lines for cell isolation. At step 208, the top absorber layer (layer 166A) is formed. In embodiments, that top absorber layer can be formed by first depositing a precursor layer by deposition (step 210) and then performing one or more of selenization, inert gas annealing and sulfuration operations (step 212). At step 214, the top buffer layer (layer 168A) is formed, such as by deposition. Next, at step 216 the P2 scribing operation is performed. At step 218, the N-type TCO layer (layer 170A) is formed, such as by deposition. Finally, a P3 scribing operation is performed at step 220 to provide the P3 scribing lines for cell isolation. A finished top circuit (110A) is provided at 222.

At steps 224 to 244 shown at the left side of FIG. 4, a very similar process is performed to form the bottom circuit 110B. Specifically, at step 224, the back substrate layer (layer 162B) is provided. At step 226, the back electrode layer (layer 164B) is formed on the substrate, such as by deposition. At step 228, a P1 scribing operation is performed to provide the P1 scribing lines for cell isolation. At step 230, the bottom absorber layer (layer 166B) is formed. In embodiments, that bottom absorber layer can be formed by first depositing a precursor layer by deposition (step 232) and then performing one or more of selenization and sulfuration operations (step 234). At step 236, the bottom buffer layer (layer 168B) is formed, such as by deposition. Next, at step 238 the P2 scribing operation is performed. At step 240, the N-type TCO layer (layer 170B) is formed, such as by deposition. Finally, a P3 scribing operation is performed at step 242 to provide the P3 scribing lines for cell isolation. A finished bottom circuit (110B) is provided at 244.

At step 246, the coupling material (layer 150) is used to mechanically couple the bottom and top circuits together to provide a tandem thin film solar module 100.

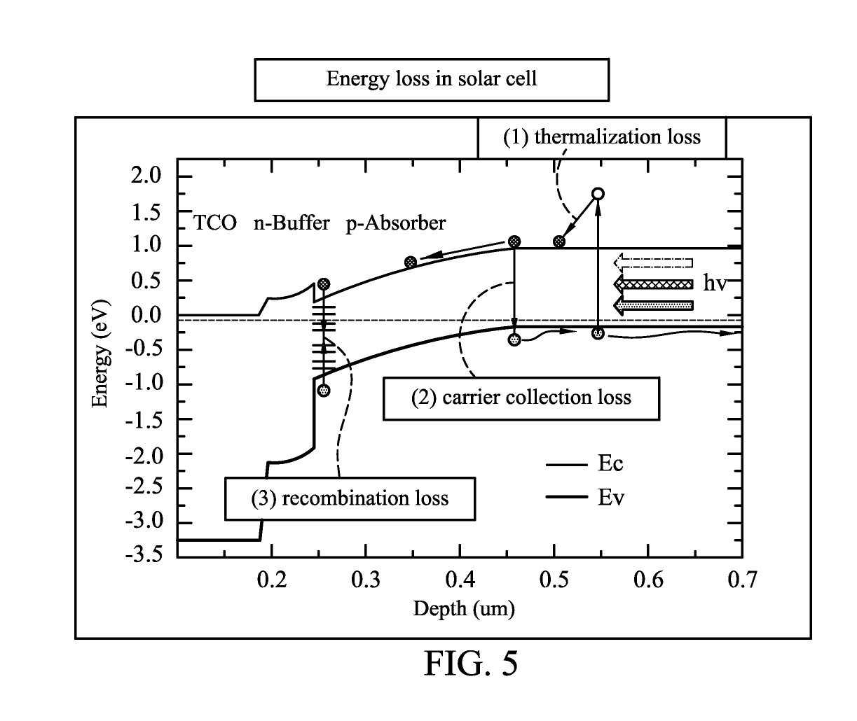

In embodiments, the tandem thin film solar module described herein provides a tandem graded band gap profile that provides several benefits, including, for example, reduced thermalization loss, reduced minority carrier collection loss, and reduced recombination loss, which improve conversion efficiency. These benefits are illustrated in part in connection with FIG. 5.

Turning first to the benefit of reduced thermalization loss, in embodiments, the tandem graded band gap profile is composed of a high band gap profile (i.e., Eg=1.5-2 eV) in the top absorber layer 166A provided of the top circuit 110A, and a low band gap profile (i.e., Eg=1.04-1.2 eV) in the bottom absorber layer 166B of the bottom circuit 110B. The high/low band gap structure improves utilization of incident light spectrum by reduced thermalization loss (shown in FIG. 5). High energy photons in incident light will be absorbed by the top absorber layer 166A with high band gap and low energy photons will be absorbed by the bottom absorber layer 166B with low band gap. This light absorption management splits light spectrum absorption to two segments of high/low photon energy and thus reduces energy gap between absorbed photon energy and material band gap of the absorber. This reduced energy gap further reduces thermalization loss and improves conversion efficiency.

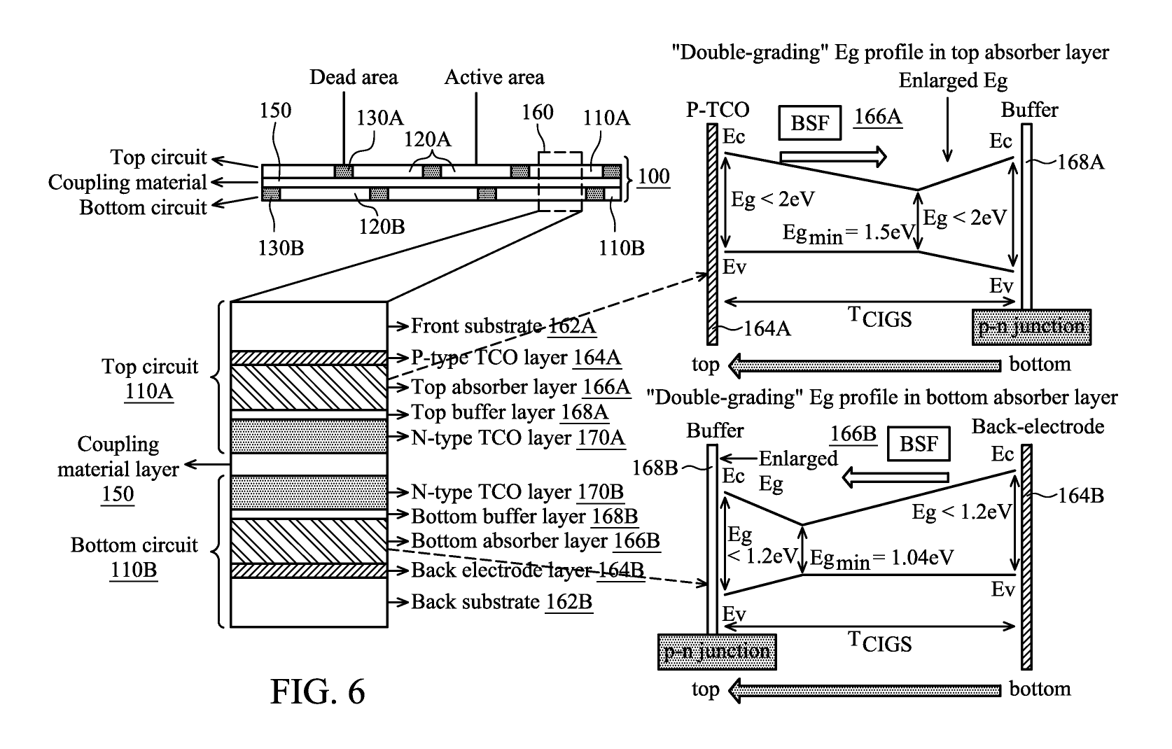

Turning to the benefit of reduced minority carrier collection loss, the tandem graded band gap profile has back surface fields (BSF) toward p-n junctions by gradient of III atoms. This is illustrated in FIG. 6. The increased Ga/(Ga+In) or Al/(Al+In) ratio away from the p-n junction increases conduction band minimum (CBM) and thus the gradient of CBM builds up an electrical field for improving electron collection. This electrical field is called the back surface field (BSF) and improves electron collection towards the p-n junction in the absorber layers. Therefore this tandem graded band gap profile reduces minority carrier collection loss (FIG. 5).

Turning now to the benefit of reduced recombination loss, the tandem graded band gap profile has enlarged band gaps near p-n junction. This can be provided by the sulfur incorporated into the absorber layers (steps 212, 234). The enlarged band gaps attributable to the sulfur-incorporation reduces recombination (FIG. 5) via defects near the p-n junction under forward bias. Therefore this tandem graded band gap profile reduces recombination loss.

The tandem thin film solar cell module can also prevent or substantially reduce CdS absorption loss to maximum benefits from CdS buffers. In conventional “CIS-based” thin film solar cells, CdS is the best buffer to reduce interface recombination loss. However, the conventional layer structure suffers CdS absorption loss, which means high energy photons (>2.4 eV) are absorbed by CdS and lose energy via recombination in the CdS layer. In the tandem thin film solar cell module described herein, high energy photons (>2.4 eV) will be absorbed by top absorber layer 166A before arriving at the CdS buffer layers 168A, 168B. This layer structure management approach prevents CdS absorption loss and also has benefits of reduced interface recombination loss from the CdS buffers.

Unlike conventional CIS-based thin film solar modules, there is no dead area in the tandem thin film solar modules. That is, the tandem module converts incident light of all optical paths to electrical power under illumination. conventional “CIS-based” thin film solar module have 5-10% total dead area that contribute no electrical power under illumination. In contrast, and with reference to FIG. 1A, the tandem “CIS-based” thin film solar module disclosed herein includes top circuit 110A and a bottom circuit 110B which are separately fabricated with different cell widths. The different cell width management of each circuit allows for a configuration where there is zero dead area, which means the tandem design converts incident light of all optical paths (e.g., optical path A (180), B (185), C (190)) to electrical power under illumination. Note that optical path A (180) passes through or is incident on both the top absorber layer of the top circuit 110A and the bottom absorber layer of the bottom circuit 110B. Optical path B (185) passes through a dead area of the top circuit and is incident on the absorber layer of the bottom circuit 110B. Finally, optical path C (190) passes through the top absorber layer of the top circuit 110A, to a dead area of the bottom circuit 110B, where it reflects off of the bottom circuit (specifically off of the back electrode layer) and back to the top absorber layer of the top circuit 110A.

As described herein, in embodiments of the tandem “CIS-based” thin film solar module, the solar module has a tandem graded band gap profile that provides for reductions in thermalization loss, minority carrier collection loss, and recombination loss. In embodiments, the layered structure also helps prevent CdS-buffer absorption loss. In embodiments, the structure of each circuit can also be arranged to provide reduce or eliminate dead areas of no-absorption in the design, allowing for conversion of incident light from all optical paths to electrical power under illumination. In embodiments, the interconnect between top and bottom circuits in this invention could be alternatively series or parallel to provide high voltage or current applications and reduce current/voltage mismatch through appropriate design of cell width in each circuit.

In one embodiment of a tandem solar module, the solar module includes a first thin film solar cell circuit comprising one or more thin film solar cells; a second thin film solar cell circuit disposed underneath the first thin film solar cell circuit and comprising one or more thin film solar cells; and a transparent coupling layer disposed between the first and second thin film circuits and securing the first and second thin film circuits together in a stack. Each solar cell circuit comprises a multi-layer structure, the multi-layer structure including a substrate, a first conductive layer formed over the substrate, a buffer layer, an absorber layer formed between the first conductive layer and the buffer layer, and a second conductive layer formed over the buffer layer, wherein the first thin film solar cell circuit and second thin film solar cell circuit are oriented with respect to one another such that the absorber layers are disposed between the substrates of the circuits, and wherein the first and second solar cell circuits have different bandgap profiles.

In another embodiment, the tandem solar module include a first thin film solar cell circuit comprising one or more thin film solar cells; a second thin film solar cell circuit disposed underneath the first thin film solar cell circuit and comprising one or more thin film solar cells; and a transparent coupling layer disposed between the first and second thin film circuits and securing the first and second thin film circuits together in a stack. Each solar cell circuit comprises a multi-layer structure, the multi-layer structure including a substrate, a first conductive layer formed over the substrate, a buffer layer, an absorber layer formed between the first conductive layer and the buffer layer, and a second conductive layer formed over the buffer layer. The first thin film solar cell circuit and second thin film solar cell circuit are oriented with respect to one another such that the absorber layers are disposed between the substrates of the circuits. The first and second solar cell circuits each have a double-graded bandgap profile, with bandgaps increasing approaching an interface between the absorber layer and the first conductive layer and approaching an interface between the absorber layer and the buffer layer. The first thin film solar cell circuit is configured for high energy photon absorption and the second thin film solar cell circuit is configured for low energy photon absorption.

In one embodiment, a method of forming a tandem solar module is provided. The method includes the steps of forming a first thin film solar cell circuit comprising one or more thin film solar cells; forming a second thin film solar cell circuit comprising one or more thin film solar cell, wherein each solar cell circuit comprises a multi-layer structure, the multi-layer structure including a substrate, a first conductive layer formed over the substrate, a buffer layer, an absorber layer formed between the first conductive layer and the buffer layer, and a second conductive layer formed over the buffer layer; disposing the second thin film solar cell circuit below the first thin film solar cell circuit; and coupling the first and second thin film solar cell circuits together with a transparent coupling layer with the first thin film solar cell circuit and second thin film solar cell circuit are oriented with respect to one another such that the absorber layers are disposed between the substrates of the circuits, wherein the first and second solar cell circuits have different bandgap profiles.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A tandem solar module comprising:
a first thin film solar cell circuit comprising one or more thin film solar cells;
a second thin film solar cell circuit disposed underneath said first thin film solar cell circuit and comprising one or more thin film solar cells; and
a transparent coupling layer disposed between the first and second thin film circuits and securing said first and second thin film circuits together in a stack,
wherein each solar cell circuit comprises a multi-layer structure, the multi-layer structure including a substrate, a first conductive layer formed over the substrate, a buffer layer, an absorber layer formed between the first conductive layer and the buffer layer, and a second conductive layer formed over the buffer layer,
wherein the first thin film solar cell circuit and second thin film solar cell circuit are oriented with respect to one another such that the absorber layers are disposed between the substrates of the circuits,
wherein the first and second solar cell circuits have different bandgap profiles.

2. The tandem solar module of claim 1, wherein the first thin film solar cell circuit comprises active areas and non-absorbing dead areas disposed between the active areas, the active areas of the first thin film solar cell circuit having a first active area width, and wherein the second thin film solar cell circuit comprises active areas and dead areas disposed between the active areas, the active areas of the second thin film solar cell circuit having a second active area width, wherein the first active area width and second active area width are different.

3. The tandem solar module of claim 2, wherein dead areas of the first thin film solar cell circuit do not overlap the dead areas of the second thin film solar cell circuit,

4. The tandem solar module of claim 1, wherein the bandgap profile of the absorber layer of the first thin film solar cell circuit is different from the bandgap profile of the absorber layer of the second thin film solar cell circuit.

5. The tandem solar module of claim 4, wherein the bandgap profiles of the solar cell circuits are double-graded bandgap profiles.

6. The tandem solar module of claim 4, wherein the bandgap profile of one of the first and second thin film solar cell circuits has a minimum bandgap greater than a maximum bandgap of the other of the first and second thin film solar cell circuits.

7. The tandem solar module of claim 6, wherein the minimum bandgap of the first thin film solar cell circuit is greater than the maximum bandgap of the second thin film solar cell circuit.

8. The tandem solar module of claim 6, wherein the absorber layers are formed from compounds selected from the group consisting of Cu(In, Al)(Se,S)₂ and Cu(In, Ga)(Se,S)₂, and the absorber layers have a graded ratio of Ga/(Ga+In) or Al/(Al+In) across the absorber layers, with the ratio being greater at areas away from an interface between the buffer layer and the absorber layer of each circuit when compared to an area proximate the interface, whereby minority carrier collection loss is reduced.

9. The tandem solar module of claim 6, wherein the absorber layers are formed from a Cu-III-(Se,S)₂ compound, and the absorber layers have a graded ratio of S/(Se+S) across the absorber layers, with the ratio being greater proximate an interface between the absorber layer and the buffer layer of each circuit when compared to an area distal to the interface, whereby recombination loss is reduced.

10. The tandem solar module of claim 1, wherein each thin film solar cell circuit is a copper-indium-selenium (CIS)-based solar cell circuit.

11. The tandem solar module of claim 1, wherein the second conductive layers of the first and second thin film solar cell circuit are transparent conductive oxide (TCO) layers of the same type.

12. The tandem solar module of claim 1, wherein first and second thin film solar cell circuits are electrically connected in parallel.

13. The tandem solar module of claim 1, wherein the first and second thin film solar cell circuit are electrically connected in series.

14. A tandem solar module comprising:
a first thin film solar cell circuit comprising one or more thin film solar cells;
a second thin film solar cell circuit disposed underneath said first thin film solar cell circuit and comprising one or more thin film solar cells; and
a transparent coupling layer disposed between the first and second thin film circuits and securing said first and second thin film circuits together in a stack,
wherein each solar cell circuit comprises a multi-layer structure, the multi-layer structure including a substrate, a first conductive layer formed over the substrate, a buffer layer, an absorber layer formed between the first conductive layer and the buffer layer, and a second conductive layer formed over the buffer layer,
wherein the first thin film solar cell circuit and second thin film solar cell circuit are oriented with respect to one another such that the absorber layers are disposed between the substrates of the circuits,
wherein the first and second solar cell circuits each have a double-graded bandgap profile, with bandgaps increasing approaching an interface between the absorber layer and the first conductive layer and approaching an interface between the absorber layer and the buffer layer,
wherein the first thin film solar cell circuit is configured for high energy photon absorption and the second thin film solar cell circuit is configured for low energy photon absorption.

15. The tandem solar module of claim 14, where the buffer layers are CdS, wherein the buffer layers are disposed such that high energy photons are absorbed in the absorber layer of the first thin film solar cell circuit before arriving at the buffer layers.

16. The tandem solar module of claim 14, wherein the minimum bandgap of the first thin film solar cell circuit is greater than the maximum bandgap of the second thin film solar cell circuit.

17. The tandem solar module of claim 14, wherein the absorber layers each are formed from a Cu-III-(Se,S)₂ compound.

18. A method of forming a tandem solar module, comprising:
forming a first thin film solar cell circuit comprising one or more thin film solar cells;
forming a second thin film solar cell circuit comprising one or more thin film solar cell, wherein each solar cell circuit comprises a multi-layer structure, the multi-layer structure including a substrate, a first conductive layer formed over the substrate, a buffer layer, an absorber layer formed between the first conductive layer and the buffer layer, and a second conductive layer formed over the buffer layer;
disposing the second thin film solar cell circuit below the first thin film solar cell circuit; and
coupling the first and second thin film solar cell circuits together with a transparent coupling layer with the first thin film solar cell circuit and second thin film solar cell circuit are oriented with respect to one another such that the absorber layers are disposed between the substrates of the circuits,
wherein the first and second solar cell circuits have different bandgap profiles.

19. The method of claim 18, wherein the first thin film solar cell circuit is configured for high energy photon absorption and the second thin film solar cell circuit is configured for low energy photon absorption.

20. The method of claim 19, wherein the first and second solar cell circuits each have a double-graded bandgap profile, with bandgaps increasing approaching an interface between the absorber layer and the first conductive layer and approaching an interface between the absorber layer and the buffer layer,
